(19) United States
(12) Patent Application Publication
(10) Pub. No.: US 2009/0261993 A1
(43) Pub. Date: Oct. 22, 2009

(54) KEYBOARD

(75) Inventors: CHENG-LIN LEE, Tu-Cheng (TW); HUNG-BIN WU, Tu-Cheng (TW); HUA-FENG WU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Taipei Hsien (TW)

(21) Appl. No.: 12/427,687

(22) Filed: Apr. 21, 2009

(30) Foreign Application Priority Data
Apr. 22, 2008 (CN) 200810301252.2

(51) Int. Cl. H03K 17/94; H04R 11/04

(52) U.S. Cl. 341/22; 381/365

(57) ABSTRACT

A keyboard includes a main body disposed with a plurality of keys and an integrated member. The integrated member is detachably connected to the main body. The integrated member is capable of being moved with respect to the main body between a first position where the integrated member and the main body forms a substantially flat surface and a second position where the integrated member is capable of being activated to receive audio inputs.

### BACKGROUND

1. Technical Field

The present disclosure relates to keyboards, and more particularly to a keyboard with extended features.

2. Description of Related Art

Keyboards are widely used as input devices for computers and other electronic devices However, because of the number of keys and the ergonomics of most keyboards, real estate are wasted on the surface of the keyboard.

Therefore, it is desired to provide a keyboard to overcome the above-described shortcomings and deficiencies.

### BRIEF DESCRIPTION OF THE DRAWINGS

FIG. 1 is a perspective view of a keyboard in accordance with an exemplary embodiment, and the keyboard includes an integrated member shown in a first position.

FIG. 2 is a perspective view of a part of the keyboard of FIG. 1.

FIG. 3 is an exploded view of a multifunction device of FIG. 1.

FIG. 4 is an enlarged view of a part of the multifunction device of FIG. 3 in accordance with the exemplary embodiment.

FIG. 5 is another perspective view of the keyboard of FIG. 1 with the integrated member shown in a second position.

### DETAILED DESCRIPTION

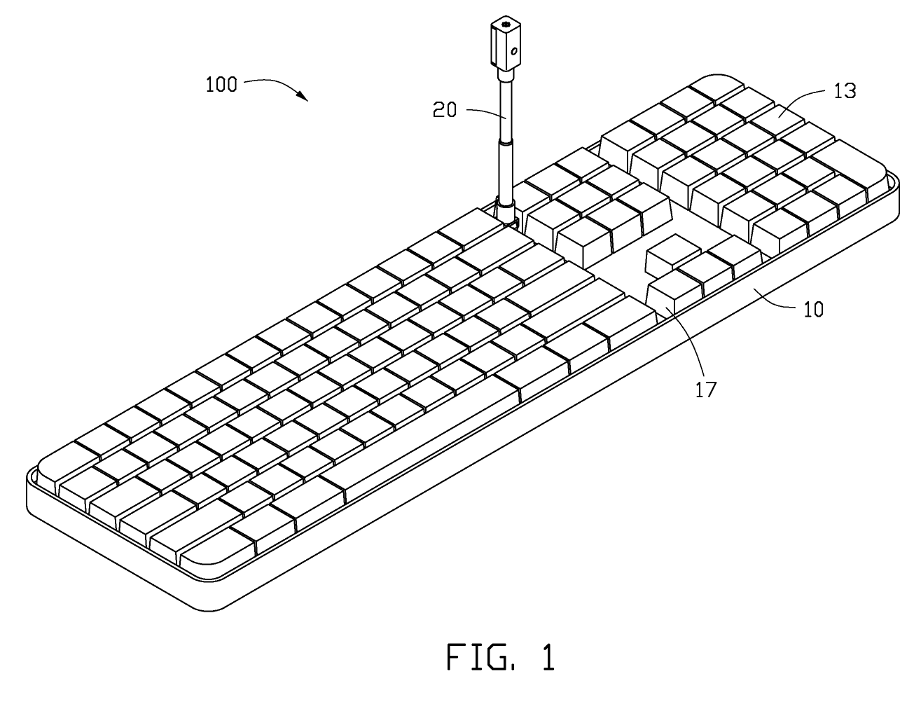

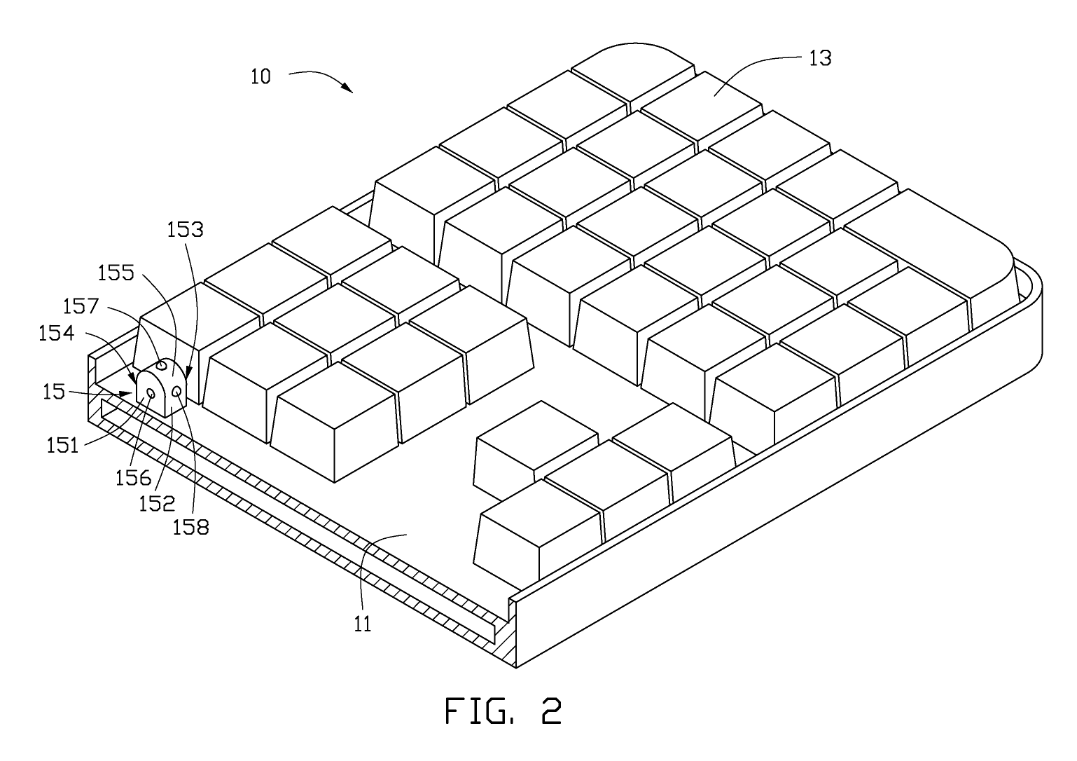

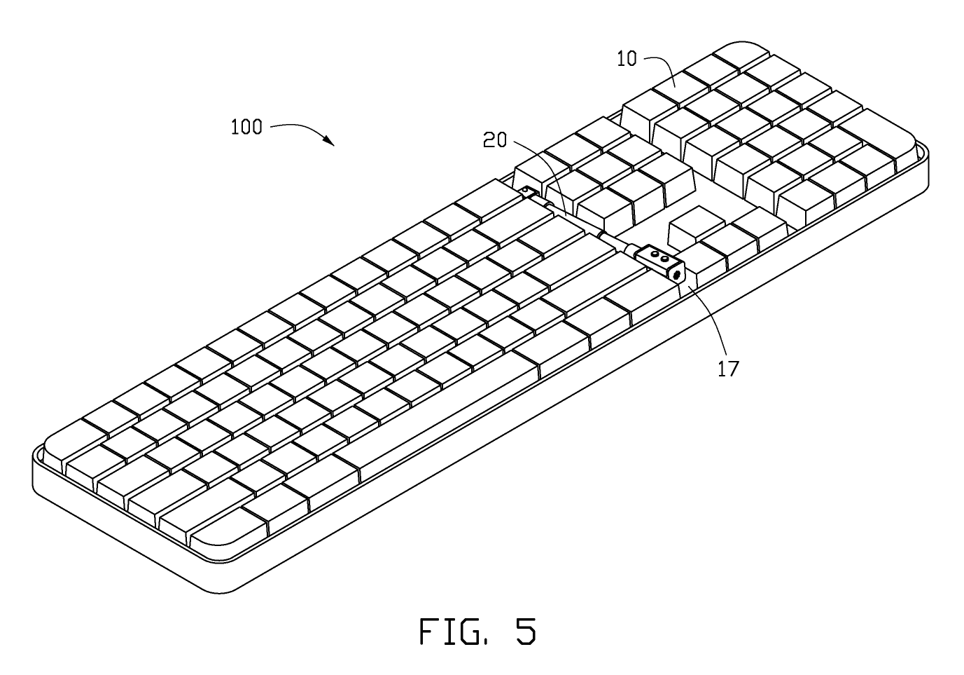

Referring to FIG. 1, a perspective view of a keyboard 100 is illustrated. The keyboard 100 generally includes a main body 10 and an integrated member 20. The main body 10 is disposed with a plurality of input keys 13 (see FIG. 2) on a top surface 11 (see FIG. 2) to receive keystrokes, so as to input information and/or commands. The integrated member 20 is selectively mounted to the main body 10, and is movable to different positions with respect to the main body 10. More specifically, the integrated member 20 is rotatable with respect to the main body 10 between a first position and a second position. In the first position (see FIG. 5), the integrated member 20 is substantially received in a receiving slot 17 defined by a set of the plurality of keys 13, and substantially coplanar with the plurality of input keys 13. In FIG. 1, the integrated member 20 is shown in the second position, where the integrated member 20 extends substantially perpendicularly from the top surface 11 of the main body 10. In this second position, the integrated member 20 may be configured to emit light to illuminate the plurality of input keys 13, and configured to receive audio inputs.

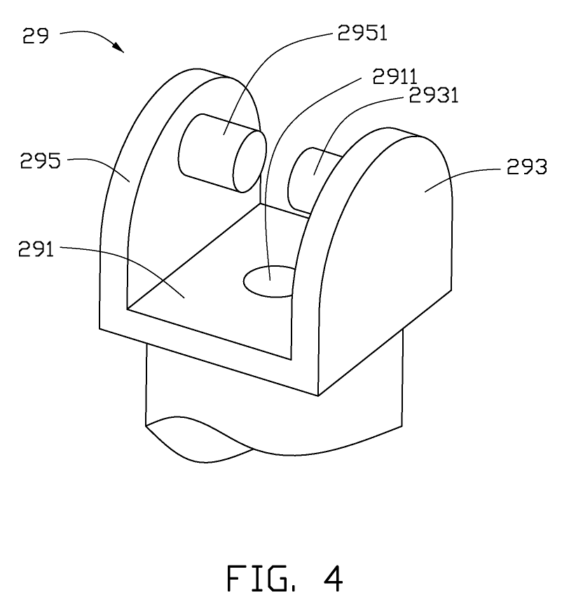

Referring to FIG. 2, a perspective view of a portion of the main body 10 is illustrated. The main body 10 is further provided with a mounting part 15 for mounting the integrated member 20. In general, the mounting part 15 is disposed adjacent to a rear edge of the main body 10. The mounting part 15 protrudes vertically from the top surface 11 of the main body 10. More specifically, the mounting part 15 includes a first surface 151, a second surface 152, a third surface 153, a fourth surface 154, and a fifth surface 155. The first surface 151, the second surface 152, the third surface 153, and the fourth surface 154 are flat surfaces. The fifth surface 155 is a top surface away from the surface 11 of the main body 10, and is curved. The fifth surface 155 interconnects the first side surface 151, the second surface 152, the third surface 153, and the fourth surface 154. The mounting part 15 further defines a through hole 156 from the first side surface 151 to the third surface 153. The fifth surface 155 is provided with a first limiting portion 157. The first limiting portion 157 is appropriately arranged for limiting a movement of the integrated member 20 when in the second position. The second surface 152 is provided with a second limiting portion 158 adjacent to a joint portion of the second surface 152 and the fifth surface 155. The second limiting portion 158 is appropriately arranged for limiting a movement of the integrated member 20 when in the first position. In this embodiment, the first limiting member 157 and the second limiting member 158 are spherical protrusions for engaging with a recess 2911 (see FIG. 4) defined in the integrated member 20 correspondingly. Further details as to the interaction of the first limiting member 157 and the second limiting member 158 with the integrated member 20 will be described hereinafter.

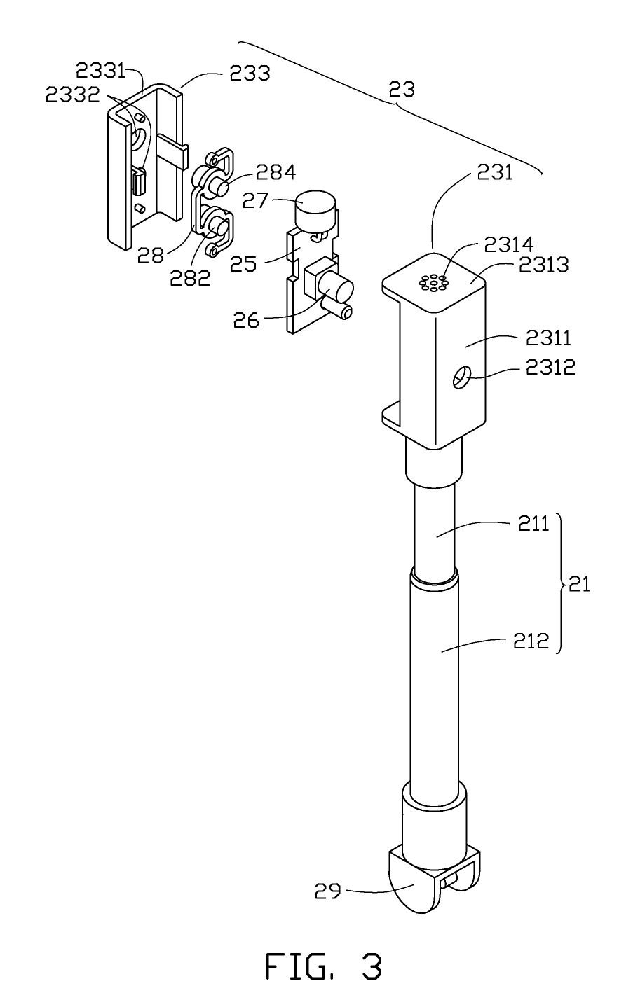

Referring to FIG. 3, the integrated member 20 includes a connecting portion 21, an integrated portion 23, and a fastening portion 29. The integrated portion 23 and the fastening portion 29 are connected to opposite ends of the connection portion 21. The connecting portion 21 includes a first tube 211 and a second tube 212. The first tube 211 and the second tube 212 are slidably sleeved to each other or in a telescoping manner, such that a distance between the integrated portion 23 and the fastening portion 29 can be adjusted according to preference.

In general, the integrated portion 23 is configured to integrate an illuminating member 26 and an audio receiving member 27. In the embodiment, the illuminating member 26 is a light emitting diode (LED), and the audio receiving member 27 is a microphone. The illuminating member 26 and the audio receiving member 27 are electrically and mechanically connected to a printed circuit board (PCB) 25.

The integrated portion 23 includes a front cover 231 and a rear cover 233. The front cover 231 and the rear cover 233 can be fastened together to define an internal space for accommodating the PCB 25, the illuminating member 26, and the audio receiving member 27. The integrated portion 23 is further provided with a switch module 28 having a first key switch 282 and a second key switch 284. The first key switch 282 and the second key switch 284 are electrically connected to the PCB 25 for activating or deactivating the illuminating member 26 and the audio receiving member 27 respectively. The first key switch 282 and the second key switch 284 partially extends out from two openings 2332 defined in the rear cover 233. With this configuration, the first key switch 282 and the second key switch 284 can be selectively actuated to control the illuminating member 26 and the audio receiving member 27 respectively.

The front cover 231 includes a front surface 2311 and a top surface 2313. The front surface 2311 defines an aperture 2312 for exposing the illuminating member 26, such that light from the illuminating member 26 illuminates the plurality of keys 13 disposed on the main body 10. The top surface 2313 is perpendicularly connected to the front surface 2311. The top surface 2313 defines a plurality of openings 2314 in a predetermined pattern, such as a circular pattern, for allowing sound to travel to the audio receiving member 27.

Referring to FIG. 4, an enlarged view of the fastening portion 29 of the integrated member 20 is illustrated. The fastening portion 29 includes a planar supporting portion 291, a first extension arm 293, and a second extension arm 295. The supporting portion 291 is connected to one end of the second tube 212 for supporting the connection portion 21 and the integrated portion 23. The first extension arm 293 and the second extension arm 295 are semi-circular, for facilitating pivotal rotation movement of the integrated member 20 with respect to the main body 10. The first extension arm 293 and the second extension arm 295 extend substantially parallel to each other in a direction of the cylindrical axis of the first tube 211 and the second tube 212. Furthermore, the first extension arm 293 and the second extension arm 295 are formed with a first pivot pin 2931 and a second pivot pin 2951 respectively. The first pivot pin 2931 and the second pivot pin 2951 extend opposite to each other, and are insertable into the through hole 156 defined in the mounting part 15. The supporting portion 291 further defines the recess 2911 in a surface opposite to a connecting portion of the connection portion 21. The recess 2911 is formed to selectively engage with the first limiting member 157 and the second limiting member 158, such that the integrated member 20 may be held at the first position or the second position.

After the integrated member 20 is mounted to the main body 10, the keyboard 100 can be operated to provide extended features. For example, the keyboard 100 can provide light under dark conditions. In this case, the integrated member 20 may be rotatably pivoted from the first position to the second position by the first pivot pin 2931 and the second pivot pin 2951. Because the first limiting member 157 engages with the recess 2911, thus, the integrated member 20 can be firmly held at the second position. Then, the first key switch 282 may be activated to turn on the illuminating member 26, such that the illuminating member 26 emits light to illuminate the plurality of input keys 13. Thereby, a particular input key on the keyboard 100 can be easily found. Furthermore, the second key switch 284 may be activated to turn on the audio receiving member 27, such that the audio inputs are received by the audio receiving member 27.

Referring to FIG. 5, when the integrated member 20 is not needed, the integrated member 20 can be rotatably pivoted from the second position to the first position by the first pivot pin 2931 and the second pivot pin 2951. Because the second limiting member 158 engages with the recess 2911, thus, the integrated member 20 can be firmly held at the first position. It is noted that when the integrated member 20 is located at the first position with respect to the main body 10, the integrated member 20 is received in the receiving slot 17. In this case, the integrated member 20 is more integratedly blended with the main body 10, without having to design additional space for the integrated member 20. Moreover, an integral appearance of the keyboard 100 looks much better.

In other embodiment, the integrated member 20 when positioned in the first position, the illuminating member 26 may also be activated to emit light, and the audio receiving member 27 may also be activated to receive audio inputs.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A keyboard, comprising:
a main body disposed with a plurality of input keys; and
an integrated member detachably connected to the main body, the integrated member capable of being moved with respect to the main body between a first position where the integrated member and the plurality of input keys are substantially coplanar and a second position where the integrated member is capable of being activated to receive audio inputs.

2. The keyboard according to claim 1, wherein the integrated member comprises an audio receiving member disposed at one end of the integrated member, the audio receiving member is capable of being activated to receive the audio inputs either at the first position or at the second position.

3. The keyboard according to claim 2, wherein the integrated member further comprises a connection portion, the connection portion comprises a first tube and a second tube connected in a telescoping manner, the first tube and a second tube moves relative to each other to adjust a height of the audio receiving member with respect to the main body.

4. The keyboard according to claim 1, wherein the integrated member comprises an illuminating member disposed at one end of the integrated member, the illuminating member is capable of emitting light so as to illuminate the plurality of input keys either at the first position or at the second position.

5. The keyboard according to claim 4, wherein the integrated member further comprises a connection portion, the connection portion comprises a first tube and a second tube connected in a telescoping manner, the first tube moves relative to the second tube to adjust a height of the illuminating member with respect to the main body.

6. The keyboard according to claim 1, wherein the integrated member comprises a fastening portion, the main body comprises a mounting part, the fastening portion is pivotably mounted to the mounting part.

7. The keyboard according to claim 6, wherein the fastening portion comprises a first limiting member and a second limiting member, the mounting part defines a recess, the recess selectively engages with the first limiting member and the second limiting member for limiting a movement of the integrated member with respect to the main body at the first position and the second position respectively.

8. A keyboard, comprising:
a main body disposed with a plurality of input keys, a set of the plurality of input keys defining a receiving slot; and
an integrated member pivotably mounted to the main body, the integrated member selectively being pivoted to be received in the receiving slot, and selectively being pivoted to a position higher than the plurality of input keys with respect to the main body.

9. The keyboard according to claim 8, wherein the integrated member comprises an audio receiving member disposed at one end of the integrated member, the audio receiving member is capable of being activated to receive audio inputs.

10. The keyboard according to claim 9, wherein the integrated member further comprises a connection portion, the connection portion comprises a first tube and a second tube connected in a telescoping manner, the first tube and a second tube moves relative to each other to adjust a height of the audio receiving member with respect to the main body.

11. The keyboard according to claim 8, wherein the integrated member comprises an illuminating member disposed at one end of the integrated member, the illuminating member is capable of emitting light so as to illuminate the plurality of input keys.

12. The keyboard according to claim 11, wherein the integrated member further comprises a connection portion, the connection portion comprises a first tube and a second tube connected in a telescoping manner, the first tube moves relative to the second tube to adjust a height of the illuminating member with respect to the main body.

13. A keyboard, comprising:
a main body disposed with a plurality of input keys; and
an integrated member mounted to the main body, the integrated member comprising:
an audio receiving member capable of being operated to receive audio inputs; and
an illuminating member capable of being operated to emit light so as to illuminate the plurality of input keys.

14. The keyboard according to claim 13, wherein the main body comprises a mounting part, the integrated member comprises a fastening portion, the mounting part is mounted to the fastening portion.

15. The keyboard according to claim 14, wherein the mounting part defines a through hole, the fastening portion includes a first extension arm and a second extension arm, the first extension arm and the second extension arm form a first pin and a second pin respectively, the first pin and the second pin are insertable into the through hole, allowing a pivotal movement of the integrated member with respect to the main body.

16. The keyboard according to claim 14, wherein the integrated member further comprises an integrated portion, the integrated portion comprises a front cover and a rear cover, the front cover and the rear cover are capable of being assembled together to accommodate the audio receiving member and the illuminating member.
